(19) United States
(12) Patent Application Publication
(10) Pub. No.: US 2011/0287568 A1
(43) Pub. Date: Nov. 24, 2011

(54) METHOD OF MANUFACTURING THIN FILM SOLAR CELL

(76) Inventors: Yuji Suzuki, Osaka (JP); Akinori Izumi, Osaka (JP); Kengo Maeda, Osaka (JP)

(21) Appl. No.: 13/148,278

(22) PCT Filed: Feb. 5, 2010
(86) PCT No.: PCT/JP2010/051679

§ 371 Date: Aug. 5, 2011

(30) Foreign Application Priority Data
Feb. 6, 2009 (JP) 2009-026208

(51) Int. Cl. H01L 31/18

(52) U.S. Cl. 438/57; 257/E31.001

(57) ABSTRACT

A method of manufacturing a thin film solar cell includes a bonding step of bonding a bus bar on a back face electrode layer of a solar cell string including a transparent conductive film, a photoelectric conversion layer and the back face electrode layer formed on a light-transmitting insulating substrate. The bonding step includes a first step of bonding conductive tape on the bonding surface of the bus bar that is to be bonded to the back face electrode layer, and a second step of bonding the bus bar to which the conductive tape has been bonded to the back face electrode layer of the solar cell string.

### TECHNICAL FIELD

The present invention relates to a method of manufacturing a thin film solar cell.

### BACKGROUND ART

Conventionally, as a thin film solar cell, an integrated thin film solar cell has been proposed in which a solar cell string is formed by connecting laminates (solar cells) in series, parallel or series-parallel. In each solar cell, a transparent conductive film made of ZnO, ITO, SnCl₂ or the like is formed on a light-transmitting insulating substrate made of glass or the like. On that film, a photoelectric conversion layer is formed including a p-layer, an i-layer and an n-layer stacked in sequence made of a thin film semiconductor such as amorphous silicon. Furthermore, a back face electrode layer made of, for example, ZnO and Ag is formed thereon (see, for example, Patent Document 1).

With the integrated thin film solar cell disclosed in Patent Document 1, it is proposed to use a bus bar connected to a back face electrode layer via a conductive paste as a power extraction electrode portion of the thin film solar cell.

Generally, adhesion between aluminum and solder is poor, and thus in the case where aluminum is used for the back face electrode layer, good adhesion between aluminum and solder can be obtained only when special solder is used.

The technique disclosed in Patent Document 1 described above is problematic in that, for example, it is difficult to provide good adhesion between aluminum and solder when aluminum is thin.

Also, in the case where a metal other than aluminum is used for the back face electrode layer, there is a possibility that the bonding strength between the back face electrode layer and the bus bar might be reduced. For this reason, there is a demand to further increase the bonding strength between the back face electrode layer and the bus bar.

Under the circumstances, in order to solve such a problem described above, the present applicant has already proposed a method of manufacturing a highly reliable thin film solar cell with which the bonding strength between the back face electrode layer and the bus bar can be improved without limiting the type of metal film constituting the back face electrode layer (see, for example, Patent Document 2).

The method of manufacturing a thin film solar cell disclosed in Patent Document 2 includes a step of forming, on a light-transmitting insulating substrate, a transparent conductive film, a photoelectric conversion layer and a back face electrode layer in this order and a bonding step of bonding a bus bar on the back face electrode layer via conductive tape, wherein the bonding step includes temporarily press-bonding the conductive tape to the back face electrode layer and permanently press-bonding the back face electrode layer to which the conductive tape has been temporarily press-bonded and the bus bar.

To describe it more specifically, for example, an anisotropic conductive film (ACF) is used as the conductive tape, and a plurality of conductive tapes are attached to a plurality of locations at a specified interval in a region of the surface of the back face electrode layer where the bus bar is to be formed. FIG. 6 is a perspective view showing an example of arrangement of conductive tapes. In FIG. 6, conductive tapes 81 each having a length X are disposed at a pitch Y on a back face electrode layer 84. In this case, the length X of the conductive tapes 81 can be, for example, approximately 3 to 10 mm, and the pitch Y can be, for example, approximately 80 to 100 mm. If it is assumed here that the region of the back face electrode layer 84 where the bus bar is to be formed has a length (in other words, the length of the solar cell itself) of approximately 1400 mm, it is necessary to bond 14 conductive tapes 81 in each bus bar-forming region of the back face electrode layer 84. In the example shown in FIG. 6, it is necessary to bond 28 conductive tapes 81 in total on the left side bus bar-forming region of the back face electrode layer 84 and the right side bus bar-forming region of the back face electrode layer 84. In some cases, a bus bar may be bonded to a center region of the back face electrode layer. In this case, it is necessary to bond 42 conductive tapes 81 in total.

After that, bus bars 91 made of, for example, flat wires are placed on respective regions of the back face electrode layer 84 to which the conductive tapes 81 have been attached, and the bus bars 91 are temporarily press-bonded to the back face electrode layer 84 by application of a heat at a relatively low temperature that does not completely cure the conductive tape 81 to the conductive tapes 81 while applying a pressure on the bus bars 91. In the case where, for example, the conductive tape 81 contains a thermosetting resin and metal particles, temporary press-bonding of the bus bars 91 to the back face electrode layer 84 can be carried out by application of a heat at a temperature that is lower than the curing temperature of the thermosetting resin by approximately 70 to 100° C. However, it is also possible to temporarily fix (temporarily press-bond) the bus bars 91 to the back face electrode layer 84 without application of a heat by utilizing the tack (stickiness) of the thermosetting resin by simply pressing the bus bars 91 against the back face electrode layer 84. Next, the bus bars 91 are permanently press-bonded to the back face electrode layer 84 by applying a heat at a temperature that cures the conductive tape 81 while applying a pressure on the bus bars 91. In the case where, for example, the conductive tape 81 contains a thermosetting resin and metal particles, the bus bars 91 can be bonded to the back face electrode layer 84 by carrying out permanent press-bonding of the bus bars 91 to the back face electrode layer 84 by application of a heat at a temperature greater than or equal to the curing temperature of the thermosetting resin (for example, 170 to 180° C.) while applying a pressure.

According to the manufacturing method described above, good adhesion can be provided between the back face electrode layer 84 and the bus bars 91 irrespective of the type of metal film constituting the back face electrode layer 84 by using the conductive tape 81 to bond the back face electrode layer 84 and the bus bars 91. As a result, good and stable conductivity can be ensured between the back face electrode layer 84 and the bus bars 91, and thus a highly reliable thin film solar cell can be obtained.

Prior Art Documents

Patent Documents

Patent Document 1: JP 2002-314104A

Patent Document 2: WO 2008/152865A1

### SUMMARY OF INVENTION

Problems to be Solved by the Invention

According to the conventional manufacturing method (disclosed in Patent Document 2), the bonding step of bonding a bus bar 91 to the back face electrode layer 84 includes: a first step of bonding conductive tapes 81 to a plurality of locations at a specified interval in a region of the surface of the back face electrode layer 84 where the bus bar is to be formed; and a second step of placing the bus bar 91 on the region of the back face electrode layer 84 to which the conductive tapes 81 have been bonded and bonding the bus bar 91 to the back face electrode layer 84 via the conductive tapes 81 by application of a heat while applying a pressure to the bus bar 91.

Specifically, when a solar cell string that has undergone appropriate processing in the preprocessing step is conveyed for the bonding step, in the bonding step, first, a first step of bonding the conductive tape 81 to a plurality of locations at a specified interval in a region of the surface of the back face electrode layer 84 where the bus bar is to be formed is carried out. As described above, in the first step, for example, 14 conductive tapes 81 are bonded to each of the right and left side regions of the back face electrode layer 84. In this case, the conductive tape 81 before being bonded has a release liner on one side thereof, and thus it is necessary to repeat a pressing step of pressing the adhesive face of the conductive tape 81 against the back face electrode layer 84 to bond the conductive tape 81 to the back face electrode layer 84 and a removing step of removing the release liner a plurality of times corresponding to the number of conductive tapes 81. In other words, in the conventional manufacturing method (disclosed in Patent Document 2), the pressing step and the removing step are repeated 28 times in total on the right and left side regions.

In the actual manufacturing line, two bonding apparatuses that reciprocally move along the back face electrode layer 84 are provided on the right and left sides of a solar cell string placed on a stage in the bonding step, and 14 conductive tapes 81 are bonded in sequence from one direction at a specified interval on each region of the back face electrode layer 84 by the corresponding one of the two bonding apparatuses.

In other words, according to the conventional manufacturing method, in the bonding step, a first step of sequentially bonding 28 conductive tapes 81 on a solar cell string conveyed from the preprocessing step is carried out. For this reason, the conventional manufacturing method is problematic in that it takes time to bond the conductive tapes 81 to the back face electrode layer 84, and therefore a longer processing time (step operating time) is required in the bonding step than those of the preceding and subsequent steps. As a result, the processing time of the entire manufacturing process of the thin film solar cell becomes long, resulting in reduced productivity.

There is another problem in that the bonding process of bonding the conductive tape 81 and the removing process of removing the release liner are repeated on the solar cell string, and thus there is a possibility that the back face electrode layer 84 might be damaged.

There is still another problem in that if the conductive tape 81 is bonded out of position or in the wrong position, it is necessary to perform an operation to remove the conductive tape 81 from the back face electrode layer 84, during which the manufacturing line needs to be stopped.

Even if the conductive tape 81 has been successfully bonded in the correct position on the back face electrode layer 84, the bus bar 91 itself has a meander and undulation and therefore the bus bar 91 is bonded to the back face electrode layer 84 in a state where the bus bar 91 is straightened by application of tension. However, it is difficult to completely eliminate the meander and undulation, thus posing a problem in that there is a possibility that the conductive tape 81 might extend beyond the bus bar 91.

Furthermore, because the bonding apparatuses for bonding the conductive tape 81 are operated on the solar cell string, there is a possibility that dust and dirt might fall onto the back face electrode layer 84 of the solar cell string. In the back face of the solar cell string, contact lines for electrically connecting the transparent conductive film and the back face electrode layer 84 are formed by splitting the photoelectric conversion layer into strips by patterning using a laser. Accordingly, if the dust and dirt that have fallen on the back face electrode layer 84 get in between the split lines, short-circuiting may occur at that portion, causing a defect in the thin film solar cell. Also, if dust and dirt fall on the surface of the back face electrode layer 84 to which the conductive tape 81 is to be bonded or on the bonded conductive tape 81, the bonding strength of the conductive tape 81 decreases, as a result of which the adhesion between the bus bar 91 and the back face electrode layer 84 is reduced. Particularly when the conductive tape is bonded not only to the right and left side regions of the back face electrode layer 84 of the solar cell string, but also to a center region of the back face electrode layer 84, it may be difficult to bond the conductive tape 81 directly to the center region of the back face electrode layer 84.

The present invention has been conceived to solve the problems described above, and it is an object of the present invention to provide a method of manufacturing a thin film solar cell with which it is possible to reduce the processing time of the bonding step, prevent the back face electrode layer from damage, and prevent a short circuit between contact lines due to dust and dirt or the like.

Means for Solving the Problems

In order to solve the problems described above, a method of manufacturing a thin film solar cell according to the present invention is a method of manufacturing a thin film solar cell including a bonding step of bonding a bus bar on a first electrode layer or a second electrode layer of a solar cell element composed of the first electrode layer, a photoelectric conversion layer and the second electrode layer formed on a light-transmitting insulating substrate, wherein the bonding step includes: a first step of bonding conductive tape to a bonding surface of the bus bar that is to be bonded to the first electrode layer or the second electrode layer; and a second step of bonding, to the first electrode layer or the second electrode layer, the bus bar to which the conductive tape has been bonded. In the above configuration, it is possible that in the first step, the conductive tape may be bonded to a plurality of locations in the bus bar at an interval, and that in the second step, the bonding surface of the bus bar may be disposed in opposed relationship with the first electrode layer or the second electrode layer, and in this state, a pressure may be applied to the bus bar while a heat is applied to the conductive tape portion so as to bond the bus bar to the first electrode layer or the second electrode layer.

According to the present invention, in the first step of the bonding step, first, the conductive tape is bonded to the bonding surface of the bus bar. Then, in the second step, the bus bar to which the conductive tape has been bonded is bonded to the first electrode layer or the second electrode layer of the solar cell element (hereinafter referred to as a solar cell string). In other words, the first step can be carried out even if the solar cell string has not arrived from the preprocessing step, which is a manufacturing step performed before the bonding step. Accordingly, the first step can be carried out simultaneously while the solar cell string is being processed in the preprocessing step. By performing the first step in advance as described above, when the solar cell string processed in the preprocessing step is conveyed to the bonding step, in the bonding step, it is only necessary to carry out the second step of bonding the bus bar to which the conductive tape has been bonded to the first electrode layer or the second electrode layer of the solar cell string, and thereby the bonding step can be completed.

According to the present invention, in the bonding step, while the second step of bonding the bus bar to the first electrode layer or the second electrode layer of the solar cell string is being carried out, the first step of bonding the conductive tape to the bus bar 21 for being bonded to the first electrode layer or the second electrode layer of the solar cell string subsequently conveyed from the preprocessing step can be simultaneously carried out. By sequentially and simultaneously performing the first step and the second step in timed relationship with sequential conveyance of the solar cell string, the processing time in the bonding step can be reduced significantly.

Also, the conductive tape is first bonded to the bus bar, and it is therefore possible to check whether or not the conductive tape extends beyond the bus bar having a meander and undulation before the bus bar is bonded to the first electrode layer or the second electrode layer. Accordingly, there is no concern that the conductive tape will extend beyond the bus bar and be out of position when the bus bar is bonded to the first electrode layer or the second electrode layer in the second step. Furthermore, even when the conductive tape is bonded out of position or in the wrong position, only the bus bar in which the conductive tape has been bonded out of position or in the wrong position can be discarded. Accordingly, unlike the conventional manufacturing method described above, the need for the operation of removing the conductive tape that has extended beyond the first electrode layer or the second electrode layer of the solar cell string can be eliminated.

Also, it is unnecessary to repeat the bonding process of bonding the conductive tape against the solar cell string and the removing process of removing the release liner, as in the conventional manufacturing method, and therefore there is no concern that the first electrode layer or the second electrode layer will be damaged.

Furthermore, the conventional manufacturing method described above requires bonding apparatuses to be operated above the solar cell string, and thus there is a possibility that dust and dirt might fall onto the first electrode layer or the second electrode layer of the solar cell string. The method of manufacturing a thin fᵢlm solar cell of the present invention, however, does not require bonding apparatuses to be operated above the solar cell string, and it is therefore possible to prevent dust and dirt from falling. For this reason, the problem encountered with the conventional manufacturing method described above, such as short-circuiting due to dust and dirt falling onto the first electrode layer or the second electrode layer and getting in between split lines, and thereby causing a defect in the solar cell string, will not occur in the manufacturing method of the present invention.

In the method of manufacturing a thin film solar cell described above, it is preferable that the conductive tape contains a thermosetting resin and conductive particles. It is also preferable that the bus bar is a conductor made of a flat wire coated with plating.

Effects of the Invention

Since the present invention has been configured as described above, in the bonding step, while the second step of bonding the bus bar to the first electrode layer or the second electrode layer of the solar cell string is being carried out, the first step of bonding the conductive tape to the bus bar 21 for being bonded to the first electrode layer or the second electrode layer of the solar cell string subsequently conveyed from the preprocessing step can be simultaneously carried out. Accordingly, the processing time in the bonding step can be reduced significantly.

### BRIEF DESCRIPTION OF DRAWINGS

FIG. 1 is a cross-sectional view showing an example of the configuration of a thin film solar cell according to an embodiment of the present invention.

FIG. 2 is a perspective view showing an example of arrangement of conductive tapes in a manufacturing method according to the embodiment of the present invention.

FIG. 3 are illustrative diagrams showing thin film solar cell manufacturing steps of the manufacturing method according to the embodiment of the present invention.

FIG. 4 is an illustrative diagram showing a wiring step of the manufacturing method of the embodiment of the present invention.

FIG. 5 is an illustrative diagram showing a laminating step of the manufacturing method of the embodiment of the present invention.

FIG. 6 is a perspective view showing an example of arrangement of conductive tapes according to a conventional manufacturing method.

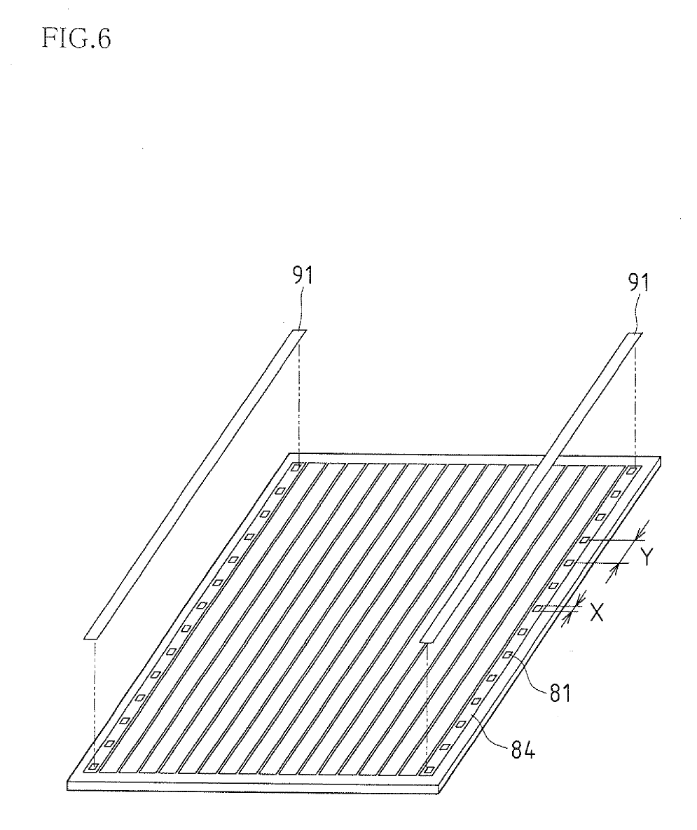

### MODES FOR CARRYING OUT THE INVENTION

Hereinafter, an embodiment of the present invention (hereinafter referred to as the present embodiment) will be described with reference to the drawings.

Description of Thin Film Solar Cell Manufactured by Manufacturing Method of the Present Embodiment

A thin film solar cell manufactured by a manufacturing method according to the present embodiment includes at least a light-transmitting insulating substrate, a transparent conductive film (corresponding to a first electrode layer of the present invention) provided on the light-transmitting insulating substrate, a photoelectric conversion layer and a back face electrode layer (corresponding to a second electrode layer of the present invention), and a bus bar provided on the back face electrode layer. The bus bar is electrically connected to the back face electrode layer by conductive tape, and thus the back face electrode layer is used as an extraction electrode. The bus bar may be connected to the transparent conductive film. In the case where the bus bar is connected to the transparent conductive film, the photoelectric conversion layer and the back face electrode layer are removed by using, for example, the second harmonic of a YAG laser or a laser such as a YVO₄ laser so as to expose the transparent conductive film, and the bus bar is electrically connected to the exposed portion with conductive tape. In this manner, by connecting the bus bar to the transparent conductive film, it is also possible to use the transparent conductive film as an extraction electrode.

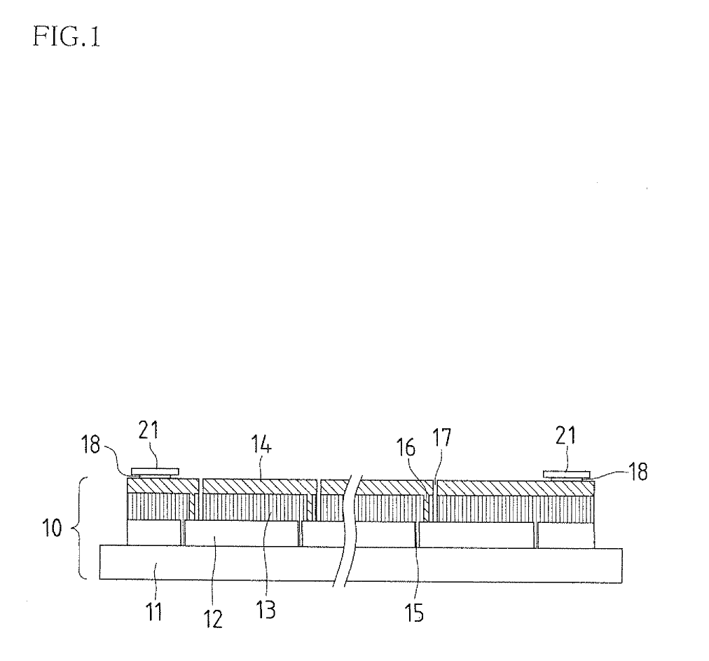

FIG. 1 is a cross-sectional view showing an example of the configuration of a thin film solar cell according to the present embodiment.

In the thin film solar cell shown in FIG. 1, a laminate (solar cell) including at least a transparent conductive film 12, a photoelectric conversion layer 13 and a back face electrode layer 14 is formed on a light-transmitting insulating substrate 11. Such laminates are connected in series, parallel or series-parallel to form a solar cell string 10. A bus bar 21 is electrically connected to the back face electrode layer 14 via conductive tape 18. In the present embodiment, good adhesion can be provided between the back face electrode layer 14 and the bus bar 21 irrespective of the type of metal film constituting the back face electrode layer 14 by using the conductive tape 18 to bond the back face electrode layer 14 and the bus bar 21. As a result, good and stable conductivity can be ensured between the back face electrode layer 14 and the bus bar 21, and thus a highly reliable thin film solar cell can be obtained.

The conductive tape 18 preferably contains a thermosetting resin and conductive particles because particularly good effects of improving the bonding strength between the back face electrode layer 14 and the bus bar 21 can be obtained irrespective of the type of the metal film constituting the back face electrode layer 14. Examples of preferred thermosetting resins include resins having a curing temperature ranging from 150 to 250° C. When the thermosetting resin has a curing temperature of 150° C. or greater, the conductive tape 18 portion has a large physical strength, and thus a thin film solar cell having particularly good reliability can be obtained. When the thermosetting resin has a curing temperature of 250° C. or less, the conductive tape 18 will not easily separate from the back face electrode layer 14 or the bus bar 21, and thus a solar cell module having particularly good reliability can be obtained. Examples of more preferred thermosetting resins include resins that cure in approximately several seconds at a curing temperature ranging from 150 to 250° C.

Specific examples of preferred thermosetting resins include resins containing an epoxy resin, acrylic resin or the like as a main component.

Examples of preferred conductive particles include Au-plated resin particles, nickel particles, nickel particles and resin particles plated with gold or the like, and so on. The conductive particles preferably have an average particle size ranging from, for example, 3 to 10 μm. If the surface of the bus bar 21 to which the conductive tape 18 is to be attached is not perfectly flat, it is preferable to use conductive tape 18 containing conductive particles having an even smaller particle size.

The conductive tape 18 preferably has a thickness, for example, ranging from 20 to 40 μm. When the conductive tape 18 has a thickness of 20 μm or greater, stable adhesion between the back face electrode layer 14 and the bus bar 21 can be obtained. When the conductive tape 18 has a thickness of 40 μm or less, conditions set for bonding can be controlled with ease, and an increase in the manufacturing cost can be suppressed.

The conductive tape 18 is preferably an anisotropic conductive tape. As used herein, the anisotropic conductive tape means an electrically anisotropic tape that provides conductivity in the thickness direction and insulation in the surface direction of the press-bonded portion. When the anisotropic conductive tape is used, particularly good effects of providing good adhesion between the back face electrode layer 14 and the bus bar 21 can be obtained irrespective of the type of metal film constituting the back face electrode layer 14.

The conductive tape 18 is preferably disposed at a plurality of locations at a specified interval. In this case, the manufacturing cost can be further reduced without compromising the reliability of the thin film solar cell.

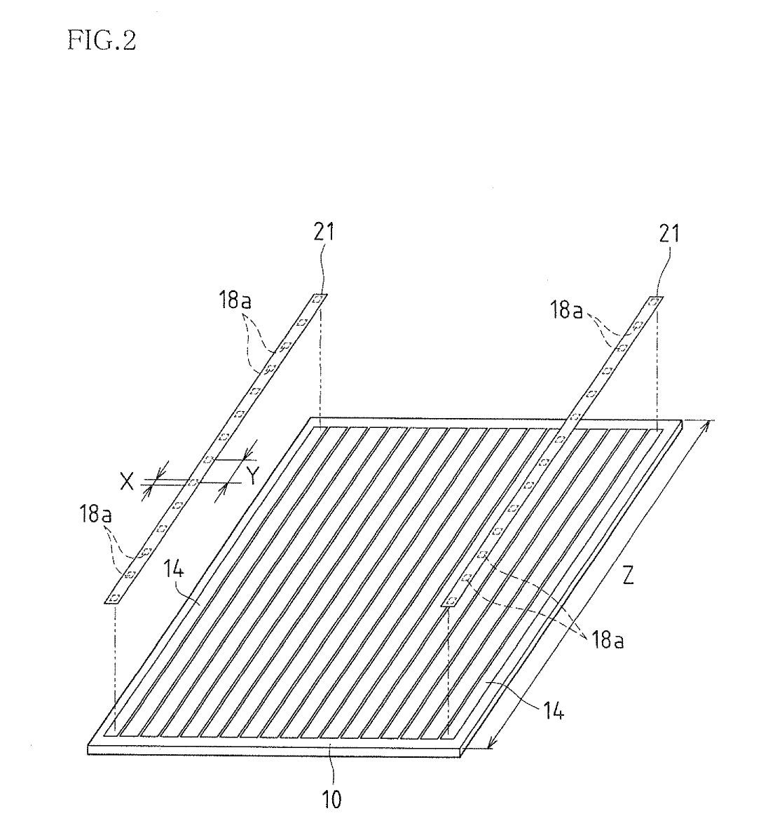

FIG. 2 is a perspective view showing an example of how the conductive tape 18 is arranged according to the present embodiment. FIG. 2 shows a state in which conductive tapes 18 have been attached to the bonding surface (the underside in FIG. 2) of each bus bar 21. In FIG. 2, an example is shown in which conductive tapes 18 each having a length X are bonded on the bonding surface of each bus bar 21 at a pitch Y. In the present embodiment, the length X can be, for example, approximately 3 to 10 mm, and the pitch Y can be, for example, approximately 80 to 100 mm. Each bus bar 21 that is bonded to the back face electrode layer 14 has a length (or in other words, the length of the solar cell string 10 itself) Z of approximately 1400 mm, and thus, for example, 12 to 17 conductive tapes 18 are bonded to the bonding surface of each bus bar 21. It is preferable that the conductive tape 18 has a width smaller than that of the bus bar 21.

As the light-transmitting insulating substrate 11, a glass substrate or the like can be used. As the transparent conductive film 12, for example, a conductive oxide capable of transmitting light such as ZnO, ITO or SnCl₂ can be used. The photoelectric conversion layer can have a structure in which, a p-layer, an i-layer and an n-layer, each made of, for example, a semiconductor thin film, are stacked in sequence. Also, as the semiconductor thin film, for example, an amorphous silicon thin film, a crystalline silicon thin film, or a combination thereof can be used.

The back face electrode layer 14 can be composed of, for example, a layer made of a conductive oxide such as ZnO and a layer made of a metal such as silver or a silver alloy. An example of more ordinary back face electrode layer 14 can be a ZnO/Ag double layer.

In the present embodiment, the back face electrode layer 14 and the bus bar 21 are electrically connected by the conductive tape 18, and therefore even when the back face electrode layer 14 has a relatively small thickness, good adhesion can be provided between the back face electrode layer 14 and the bus bar 21.

As the bus bar 21, it is preferable to use a conductor made of a flat wire coated with plating. Accordingly, it is possible to select a bus bar that does not contain a solder component, and thus an increase in the manufacturing cost can be suppressed. As the plating material, for example, nickel plating or the like can be used.

### Description of Method of Manufacturing Thin Film Solar Cell According to the Present Embodiment

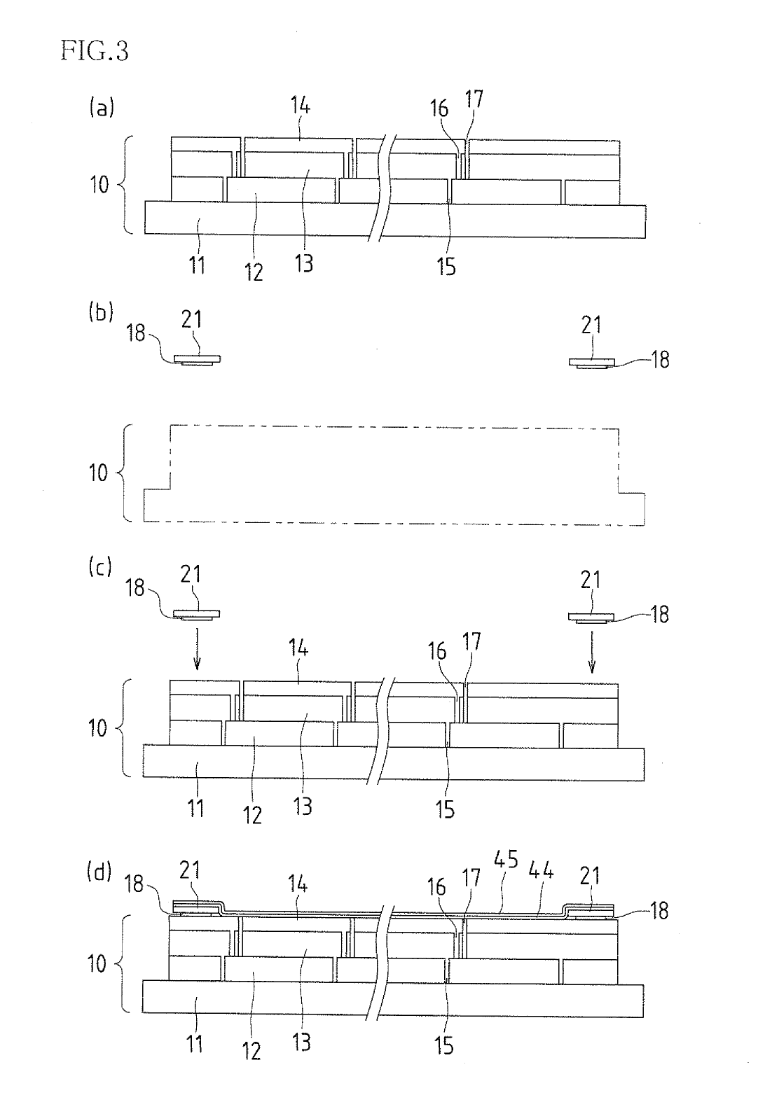

Next, a method of manufacturing a thin film solar cell configured as described above will be described in several steps including a step of forming a solar cell string 10, a bonding step and a wiring and laminating step, with reference to FIGS. 3(3(a),3(b),3(c),3(d)) to 5.

(1) Step of Forming Solar Cell String 10 (see FIG. 3(a))

First, a transparent conductive film 12 is formed on a light-transmitting insulating substrate 11 such as a glass substrate, using, for example, SnO₂ (tin oxide) by a thermal CVD method or the like. Next, patterning is performed on the transparent conductive film 12 using the fundamental wave of a YAG laser or the like. Next, laser light is caused to be incident upon the surface of the light-transmitting insulating substrate 11 (glass substrate surface) to split the transparent conductive film 12 into strips, forming split lines 15, after which the substrate is ultrasonically cleaned in pure water to form a photoelectric conversion layer 13. As the photoelectric conversion layer 13, for example, a film including an upper (light-receiving face-side) cell composed of an a-Si:H p-layer, an a-Si:H i-layer and a μc-Si:H n-layer and a lower cell composed of a μc-Si:H p-layer, a μc-Si:H i-layer and a μc-Si:H n-layer is formed.

Next, patterning is performed on the photoelectric conversion layer 13 by using, for example, the second harmonic of a YAG laser or a YVO₄ laser. Laser light is caused to be incident upon the glass substrate surface to split the photoelectric conversion layer 13 into strips, forming contact lines 16 for electrically connecting the transparent conductive film 12 and a back face electrode layer 14.

Next, a ZnO (zinc oxide)/Ag film is formed as the back face electrode layer 14 by a magnetron sputtering method or the like. The thickness of the ZnO film can be approximately 50 nm. Instead of the ZnO film, a film having high light-transmitting properties may be used such as ITO or SnO₂. The thickness of the silver film can be approximately 125 nm. In the back face electrode layer 14, the transparent conductive film such as ZnO may be omitted, but it is desirable to have the transparent conductive film in order to obtain a high conversion efficiency.

Next, patterning is performed on the back face electrode layer 14 using a laser. Laser light is caused to be incident upon the glass substrate surface to split the back face electrode layer 14 into strips, forming split lines 17. At this time, in order to avoid damage by the laser to the transparent conductive film 12, as the laser, it is preferable to use the second harmonic of a YAG laser or the like having good penetrability to the transparent conductive film 12. It is also possible to use a YVO₄ laser. Also, it is preferable to select processing conditions that minimize damage to the transparent conductive film 12 and suppress the occurrence of burrs in the processed silver electrode of the back face electrode layer 14.

A solar cell string 10 as shown in FIG. 3(a) is formed in the manner described above.

(2) Bonding Step (see FIGS. 3(b) and 3(c))

In the bonding step, an anisotropic conductive film (AFC) is used as the conductive tape 18, and a first step of bonding the conductive tape 18 to the bonding surface of a bus bar 21 for being bonded to the back face electrode layer 14 (see FIG. 3(b)) and a second step of bonding the bus bar 21 to which the conductive tape 18 has been bonded to the back face electrode layer 14 of the solar cell string 10 (see FIG. 3(c)) are carried out.

In the first step, first, the conductive tape 18 is bonded to a plurality of locations of each bus bar 21 at a specified interval. Specifically, as shown in FIG. 2, conductive tapes 18 each having a length X is disposed on and attached to the bonding surface of the bus bar 21 at a pitch Y. In this case, if the length X of the conductive tape 18 is, for example, 10 mm and the pitch Y is, for example, 100 mm, the length of the bus bar 21 will be 1400 mm, and thus 14 conductive tapes 18 will be bonded to the bonding surface of each bus bar 21. In the configuration shown in FIG. 2, 28 conductive tapes 18 are bonded in total on the adhesive faces of two bus bars 21, namely, the left side bus bar 21 and the right side bus bar 21.

In the second step, the bus bars 21 to which the conductive tape 18 was bonded to the bonding surface thereof in the first step are placed at respective locations on the back face electrode layer 14 of a solar cell string 10 that has been conveyed from the preprocessing step, and temporarily bonded by application of a heat at a relatively low temperature that does not completely cure the conductive tape 81 while applying a pressure on the bus bars 21. In the case where, for example, the conductive tape contains a thermosetting resin and metal particles, temporary bonding is carried out by application of a heat at a temperature of approximately 70 to 100° C., which is lower than the curing temperature of the thermosetting resin. However, with respect to the temporary bonding, it is also possible to temporarily fix (temporarily bond) the bus bars without application of a heat by utilizing the tack (stickiness) of the thermosetting resin by simply pressing the bus bars against the back face electrode layer. Next, the bus bars 21 are permanently bonded by application of a heat at a temperature that cures the conductive tape 18 while applying a pressure on the bus bars 21. In the case where, for example, the conductive tape 81 contains a thermosetting resin and metal particles, permanent bonding is carried out by application of a heat at a temperature greater than or equal to the curing temperature of the thermosetting resin, for example, approximately 170 to 180° C. It is thereby possible to bond the bus bars 21 to the back face electrode layer 14.

(3) Wiring and Laminating Step (see FIGS. 3(d), 4 and 5)

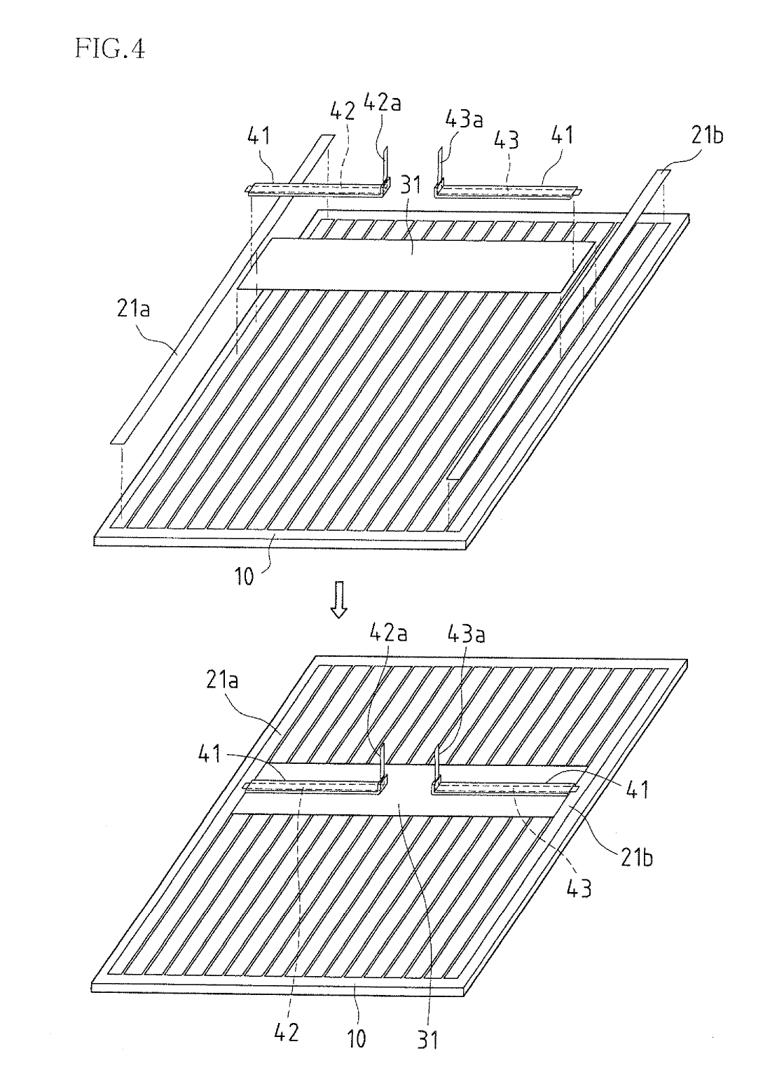

Next, as shown in FIG. 4, an EVA sheet 31 for bonding is disposed on the solar cell string 10 configured as described above. On the EVA sheet 31, a positive electrode lead wire 42 and a negative electrode lead wire 43 that are made of flat cables and covered with an insulating film 41 are disposed in line (or parallel, i.e., disposed offset in the width direction), with their tips opposing each other. Then, one end of the positive electrode lead wire 42 is connected to a center position of a bus bar (positive electrode current collecting portion) 21a, and the other end is positioned at substantially the center of the solar cell string 10 and bent at a predetermined angle (perpendicularly in FIG. 4) with respect to the face of the solar cell string 10 to serve as a power lead portion 42a. Likewise, one end of the negative electrode lead wire 43 is connected to a center position of another bus bar (negative electrode current collecting portion) 21b, and the other end is positioned at substantially the center of the solar cell string 10 and bent at a predetermined angle (perpendicularly in FIG. 4) with respect to the face of the solar cell string 10 to serve as a power lead portion 43a.

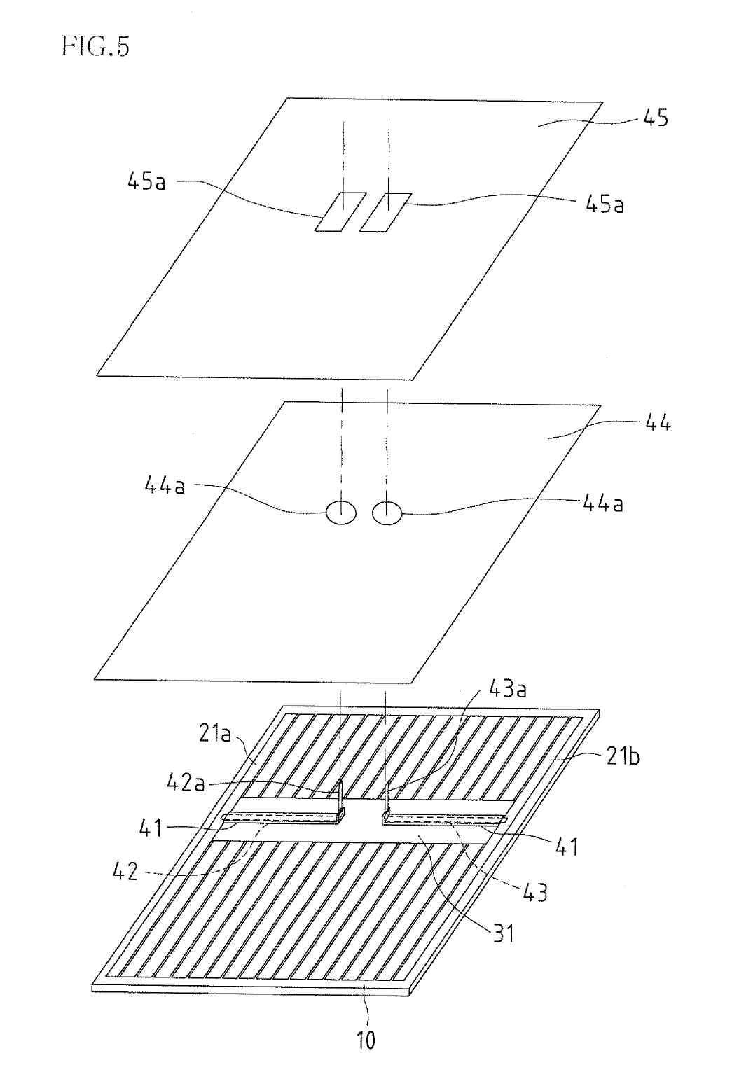

In the arrangement of the constituent elements shown in FIG. 4, the power lead portions 42a and 43a of the positive electrode lead wire 42 and the negative electrode lead wire 43 are passed through openings 44a and 45a as shown in FIG. 5, so as to dispose a sealing insulating film 44 and a back film 45 serving as a back face protective sheet for weather resistance and high insulation. Through a laminating step and a curing step performed in this state, the back film 45 is laminated and sealed on the entire face of the solar cell string 10, and thereby a thin film solar cell (see FIG. 3(d)) is obtained.

As can be seen from the above description, according to the manufacturing method of the present embodiment, in the first step of the bonding step, first, conductive tape 18 is bonded to the bonding surface of a bus bar 21, and thereafter in the second step, the bus bar 21 to which the conductive tape 18 has been bonded is bonded (including temporary bonding and permanent bonding) to the back face electrode layer 14 of the solar cell string 10. In other words, the first step can be carried out even if the solar cell string 10 has not arrived from the preprocessing step. Accordingly, the first step can be carried out simultaneously while the solar cell string 10 is being processed in the preprocessing step. By performing the first step in advance as described above, when the solar cell string 10 processed in the preprocessing step is conveyed to the bonding step, in the bonding step, it is only necessary to carry out the second step of positioning and bonding the bus bars 21 to which the conductive tape 18 has been bonded to the back face electrode layer 14 of the solar cell string 10 with high accuracy, and thereby the bonding step can be completed.

In other words, according to the manufacturing method of the present embodiment, in the bonding step, while the second step of bonding the bus bar 21 to the back face electrode layer 14 of the solar cell string 10 is being carried out, the first step of bonding the conductive tape 18 to the bus bar 21 for being bonded to the back face electrode layer 14 of a solar cell string 10 subsequently conveyed from the preprocessing step can be simultaneously carried out. By sequentially and simultaneously performing the first step and the second step in timed relationship with sequential conveyance of the solar cell string, the processing time in the bonding step can be reduced significantly.

Also, the conductive tape 18 is first bonded to each bus bar 21, and it is therefore possible to check whether or not the conductive tape 18 extends beyond the bus bar 21 having a meander and undulation before the bus bar 21 is bonded to the back face electrode layer 14. Accordingly, there is no concern that the conductive tape 18 will extend beyond the bus bar 21 and be out of position when the bus bar 21 is bonded to the back face electrode layer 14 in the second step. Furthermore, even when the conductive tape 18 is bonded out of position or in the wrong position, only the bus bar 21 in which the conductive tape 18 has been bonded out of position or in the wrong position can be redone or discarded. Accordingly, unlike the conventional manufacturing method described above, the need for the operation of removing the conductive tape 18 that has extended beyond the back face electrode layer 14 of the solar cell string 10 can be eliminated.

Also, it is unnecessary to repeat the pressing process of pressing the conductive tape against the solar cell string and the removing process of removing the release liner, as in the conventional manufacturing method, and therefore there is no concern that the back face electrode layer will be damaged.

Furthermore, the conventional manufacturing method described above requires bonding apparatuses to be operated above the solar cell string, and thus there is a possibility that dust and dirt might fall onto the back face electrode layer of the solar cell string. The manufacturing method of the present embodiment, however, does not require bonding apparatuses to be operated above the solar cell string, and it is therefore possible to prevent dust and dirt from falling. For this reason, the problem encountered with the conventional manufacturing method described above, such as short-circuiting due to dust and dirt falling onto the back face electrode layer and getting in between contact lines, and thereby causing a defect in the solar cell string, will not occur in the manufacturing method of the present embodiment.

The present invention may be embodied in various other forms without departing from the gist or essential characteristics thereof. Therefore, the embodiment described above is to be considered in all respects as illustrative and not limiting. The scope of the invention is indicated by the appended claims rather than by the foregoing description. Furthermore, all variations and modifications within a scope equivalent to the scope of the claims are encompassed in the scope of the present invention.

This application claims priority on Japanese Patent Application No. 2009-026208 filed in Japan on Feb. 6, 2009, the content of which is incorporated herein by reference.

### INDUSTRIAL APPLICABILITY

The present invention is suitable for a method of manufacturing a thin film solar cell.

### DESCRIPTION OF REFERENCE NUMERALS

10 Solar Cell String

11 Light-Transmitting Insulating Substrate

12 Transparent Conductive Film (First Electrode Layer)

13 Photoelectric Conversion Layer

14 Back Face Electrode Layer (Second Electrode Layer)

15, 17 Split Line

16 Contact Line

18 Conductive Tape

21 (21a, 21b) Bus Bar

31 EVA Sheet

41 Insulating Film

42 Positive Electrode Lead Wire

42a, 43a Power Lead Portion

43 Negative Electrode Lead Wire

44 Sealing Insulating Film

44a, 45a Opening

45 Back Film (Back Face Protective Sheet)

1. A method of manufacturing a thin film solar cell including a bonding step of bonding a bus bar on a first electrode layer or a second electrode layer of a solar cell element composed of the first electrode layer, a photoelectric conversion layer and the second electrode layer formed on a light-transmitting insulating substrate,
wherein the bonding step comprises:
a first step of bonding conductive tape to a bonding surface of the bus bar that is to be bonded to the first electrode layer or the second electrode layer; and
a second step of bonding, to the first electrode layer or the second electrode layer, the bus bar to which the conductive tape has been bonded.

2. The method of manufacturing a thin film solar cell according to claim 1,
wherein in the first step, the conductive tape is bonded to a plurality of locations in the bus bar at an interval, and
in the second step, the bonding surface of the bus bar is disposed in opposed relationship with the first electrode layer or the second electrode layer, and in this state, a pressure is applied to the bus bar while a heat is applied to the conductive tape portion so as to bond the bus bar to the first electrode layer or the second electrode layer.

3. The method of manufacturing a thin film solar cell according to claim 1,
wherein the conductive tape contains a thermosetting resin and conductive particles.

4. The method of manufacturing a thin film solar cell according to claim 1,
wherein the bus bar is a conductor made of a flat wire coated with plating.
